(19) United States
(12) Patent Application Publication
(10) Pub. No.: US 2023/0205956 A1
(43) Pub. Date: Jun. 29, 2023

(54) NEURAL NETWORK WITH ON-THE-FLY GENERATION OF THE NETWORK PARAMETERS

(71) Applicant: Commissariat à l'Energie Atomique et aux Energies Alternatives, Paris (FR)

(72) Inventors: William GUICQUERO, Grenoble (FR); Van-Thien NGUYEN, Grenoble (FR)

(21) Appl. No.: 18/145,236

(22) Filed: Dec. 22, 2022

(30) Foreign Application Priority Data
Dec. 24, 2021 (FR) 2114471

(51) Int. Cl. G06F 30/27; G06N 3/045

(52) U.S. Cl. CPC G06F 30/27; G06N 3/045

(57) ABSTRACT

The present description concerns a circuit comprising: a number generator (205) configured to generate a sequence of vectors (207, 219) of size , the vector sequence being the same at each start-up of the number generator; a memory (211) configured to store a set of first parameters (Ω) of an auxiliary neural network (204); a processing device configured to generate a set of second parameters of a layer (201) of a main neural network by the application a plurality of times of a first operation (g), by the auxiliary neural network, performing a generation operation from each vector generated by the number generator, each generation delivering a vector of second parameters, the set of the vectors of second parameters forming said set of second parameters; and wherein the number of second parameters is greater than the number of first parameters.

### FIELD

The present disclosure generally concerns artificial neural networks and more particularly the generation of parameters of a deep neural network by a circuit dedicated to this task.

### BACKGROUND

Artificial neural networks (ANNs) are computing architectures developed to imitate, within a certain extent, the human brain function.

Among artificial neural networks, deep neural networks (DNNs) are formed of a plurality of so-called hidden layers comprising a plurality of artificial neurons. Each artificial neuron of a hidden layer is connected to the neurons of the previous hidden layer or of a subset of the previous layers via synapses generally represented by a matrix having its coefficients representing synaptic weights. Each neuron of a hidden layer receives, as input data, output data generated by artificial neurons of the previous layer(s) and generates in turn output data depending, among others, on the weights connecting the neuron to the neurons of the previous layer(s).

Deep neural networks are powerful and efficient tools, in particular when their number of hidden layers and of artificial neurons is high. However, the use of such networks is limited by the size of the memories and the power of the electronic devices on which the networks are implemented. Indeed, the electronic device implementing such a network should be capable of containing the weights and parameters, as well as of having a sufficient computing power, according to the network operation.

### SUMMARY

There is a need to decrease the needs in terms of resources (memory, power, etc.) of a deep neural network implemented in an electronic device.

An embodiment overcomes all or part of the disadvantages of hardware implementations of known deep neural networks.

An embodiment provides a circuit comprising: a number generator configured to generate a sequence of vectors of size m, the vector sequence being, for example, the same at each start-up of the number generator; a memory configured to store a set of first parameters of an auxiliary neural network; a processing device configured to generate a set of second parameters of a layer of a main neural network by the application a plurality of times of a first operation, by the auxiliary neural network, performing a generation operation from each vector generated by the number generator, each generation delivering a vector of second parameters, the set of the vectors of second parameters forming said set of second parameters; and wherein the number of second parameters is greater than the number of first parameters.

According to an embodiment, the first operation is non-linear.

According to an embodiment, the circuit further comprises a volatile memory (209) configured to store the vectors of the vector sequence.

According to an embodiment, the number generator is configured to store the first vector into a register type memory, for example the volatile memory, and to generate a second vector, wherein the second vector is stored in the memory, causing the suppression of the first vector.

According to an embodiment, the processing device is further configured to perform an inference operation through said layer of the main neural network by applying at least one second function based on the second parameters and on an input vector of said layer, the operation of inference through the neuron layer delivering an output vector, and wherein the size n₀ of the output vector is greater than the size m of a vector generated by the number generator.

According to an embodiment, wherein the output vector is generated, by the layer of the main neural network, coordinate by coordinate, by application of at least the second function to the second parameters and to the input vector.

According to an embodiment, the input vector is an image.

According to an embodiment, the layer of the main neural network is a dense layer.

According to an embodiment, the layer of the main neural network is a convolutional layer.

According to an embodiment, the number generator is a cellular automaton.

According to an embodiment, the number generator is a pseudo-random number generator,.

According to an embodiment, the number generator a linear feedback shift register.

An embodiment provides a compiler implemented by computer by a circuit design tool such as hereabove, the compiler receiving a topological description of a circuit, the topological description specifying the first and second function as well as the configuration of the number generator, the compiler being configured to determine whether the first operation is linear or non-linear, and if the first operation is non-linear, the compiler being configured to generate a design file for a circuit such as hereabove.

According to an embodiment, the compiler is configured to perform, in the case where the first operation is linear, the design of a circuit so that the circuit implements a decomposition of operations by sequentially applying a third operation and a fourth operation equivalent to the combination of the first operation and of the second operation, the third operation taking as input variables the input vector and the first parameters and the fourth operation taking as inputs the sequence of vectors generated by the number generator and the output of the third operation and delivering said output vector.

An embodiment provides a method of computer design of an above circuit, comprising, prior to the implementation of a compiler such as hereabove, the implementation of a method for searching for the optimal topology of main and/or generative neural network, and delivering said topological description data to said compiler.

An embodiment provides a data processing method comprising, during an inference phase: the generation of a vector sequence of size m, by a number generator, the vector sequence being the same at each start-up of the number generator; the storage of a set of first parameters of an auxiliary neural network in a memory; the generation, by a processing device, of a set of second parameters of a layer of a main neural network by application a plurality of times of a first operation, by the auxiliary neural network, performing an operation of generation from each vector generated by the number generator, each generation delivering a vector of second parameters, the set of vectors of second parameters forming said set of second parameters; and wherein the number of second parameters is greater than the number of first parameters.

According to an embodiment, the method hereabove further comprises a phase of learning of the auxiliary neural network, prior to the inference phase, the learning phase comprising the learning of a matrix of weights, based on the vector sequence generated by the number generator, the vector sequence being identical to the vector sequence generated in the inference phase.

### BRIEF DESCRIPTION OF THE DRAWINGS

The foregoing features and advantages, as well as others, will be described in detail in the rest of the disclosure of specific embodiments given by way of illustration and not limitation with reference to the accompanying drawings, in which:

FIG. 1 illustrates an example of a layer of a deep neural network;

FIG. 2A illustrates an example of implementation of a dense layer of a deep neural network according to an embodiment of the present disclosure;

FIG. 2B illustrates another example of implementation of a dense layer of a deep neural network according to an embodiment of the present disclosure;

FIG. 2C illustrates an example of implementation of an auxiliary neural network according to an embodiment of the present disclosure;

FIG. 3 illustrates another example of implementation of a dense layer of a deep neural network according to an embodiment of the present disclosure;

FIG. 4 illustrates an example of a model of a deep neural network comprising dense layers as illustrated in FIGS. 2A, 2B, or 3;

FIG. 5 illustrates an example of implementation of a convolutional layer of a deep neural network according to an embodiment of the present disclosure;

FIG. 6 illustrates another example of implementation of a convolutional layer of a deep neural network according to an embodiment of the present disclosure;

FIG. 7 is an example of a model of a deep neural network comprising convolutional layers as illustrated in FIGS. 5 or 6;

FIG. 8 is a block diagram illustrating an implementation of a compiler configured to generate a circuit design;

FIG. 9 is a block diagram illustrating an implementation of an automated neural architecture search tool according to an embodiment of the present disclosure; and

FIG. 10 illustrates a hardware system according to an example of embodiment of the present disclosure.

### DETAILED DESCRIPTION OF THE PRESENT EMBODIMENTS

Like features have been designated by like references in the various figures. In particular, the structural and/or functional features that are common among the various embodiments may have the same references and may dispose identical structural, dimensional and material properties.

For the sake of clarity, only the steps and elements that are useful for an understanding of the embodiments described herein have been illustrated and described in detail. In particular, the learning methods, as well as the operation, of a neural network are not described in detail and are within the abilities of those skilled in the art.

Unless indicated otherwise, when reference is made to two elements connected together, this signifies a direct connection without any intermediate elements other than conductors, and when reference is made to two elements coupled together, this signifies that these two elements can be connected or they can be coupled via one or more other elements.

In the following disclosure, unless otherwise specified, when reference is made to absolute positional qualifiers, such as the terms “front”, “back”, “top”, “bottom”, “left”, “right”, etc., or to relative positional qualifiers, such as the terms “above”, “below”, “upper”, “lower”, etc., or to qualifiers of orientation, such as “horizontal”, “vertical”, etc., reference is made to the orientation shown in the figures.

Unless specified otherwise, the expressions “around”, “approximately”, “substantially” and “in the order of” signify within 10%, and preferably within 5%.

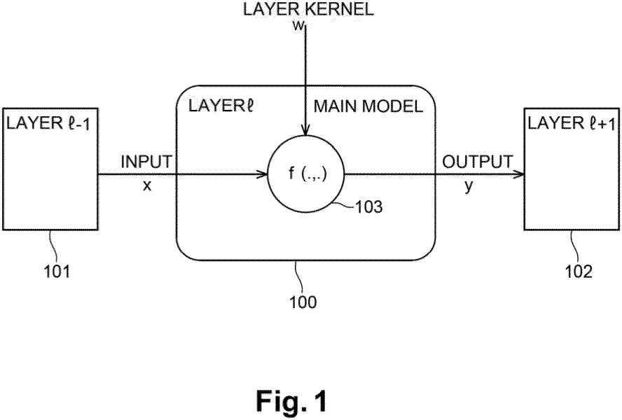

FIG. 1 shows an example of a layer 100 (LAYER 1, MAIN MODEL) of a deep neural network.

Layer 100 takes as input data an object x (INPUT x), for example, a vector, and generates, from this input data, an output data y (OUTPUT). The input data y is for example a vector having a size identical to or different from the input vector x.

The deep neural network comprising layer 100 for example comprises a layer 101 (LAYER 1-1) powering layer 100 and/or a layer 102 (LAYER 1+1) powered by layer 100. Although the example of FIG. 1 illustrates a layer 100 powered by a previous layer and powering a next layer, those skilled in the art will be capable of adapting to other models, particularly to models where layer 100 is powered by a plurality of neurons belonging to a plurality of other layers and/or powers a plurality of neurons belonging to a plurality of other layers. Layer 101 is for example an input layer of the deep neural network and generates, from input data (not illustrated) of the network, data x which is then supplied to layer 100. Layer 102 is for example an output layer of the neural network and generates output data from the output data y generated by layer 100. As an example, the number of neurons forming layers 101 and 102 is smaller than the number of neurons forming layer 100. In other examples, the neural network comprises other additional neuron layers before and/or after layers 100, 101, and 102, or only comprises layer 100.

Layer 100 is for example a dense layer, that is, each of the artificial neurons forming it is connected to each of the artificial neurons forming the previous layer as well as to each of the neurons forming the next layer. In other examples, layer 100 is a convolutional layer, a dense layer, or another type of layer coupled to synapses having a weight. The neural network generally comprises a plurality of types of layers.

Layer 100 performs a layer operation 103 (f(. , . ) ) taking as an input for example input data x and a matrix of weight W (LAYER KERNEL) to generate output data y. As an example, when layer 100 is a dense layer, operation 103 comprises applying any mathematically function, such as for example:

$$f \left(W , x\right) = W x .$$

Generally, the nature of operation 103 depends on the type of layer 100 as well as on its role in the operation and the use of the neural network. Generally, layer operation 103 f comprises a first linear operation, between two tensors, which may be taken down to a multiplicative operation between a matrix and a vector, possible followed by a second function, linear or non-linear.

The storage of the matrix of weights W, as well as of the similar matrices associated with the other layers, is generally performed by a memory. However, weight matrices having a relatively large size, their storage is memory space intensive.

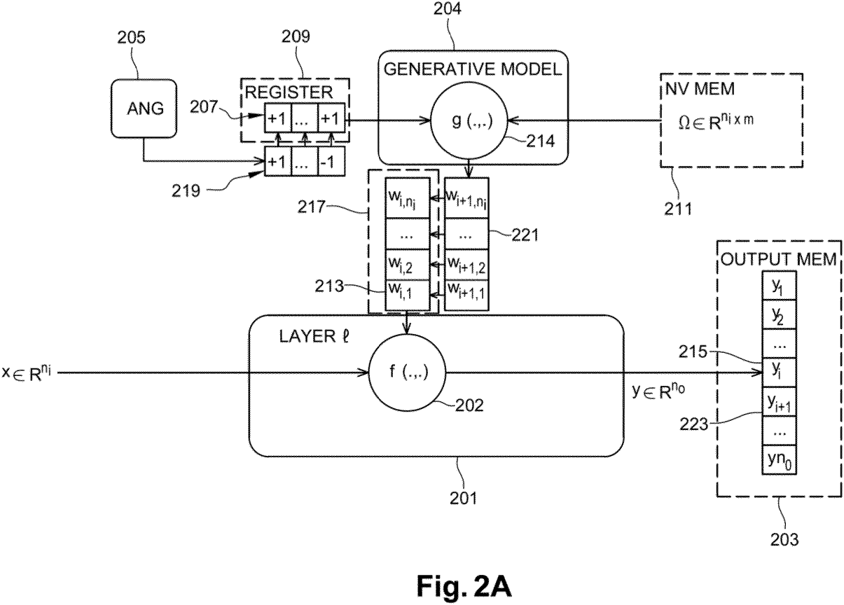

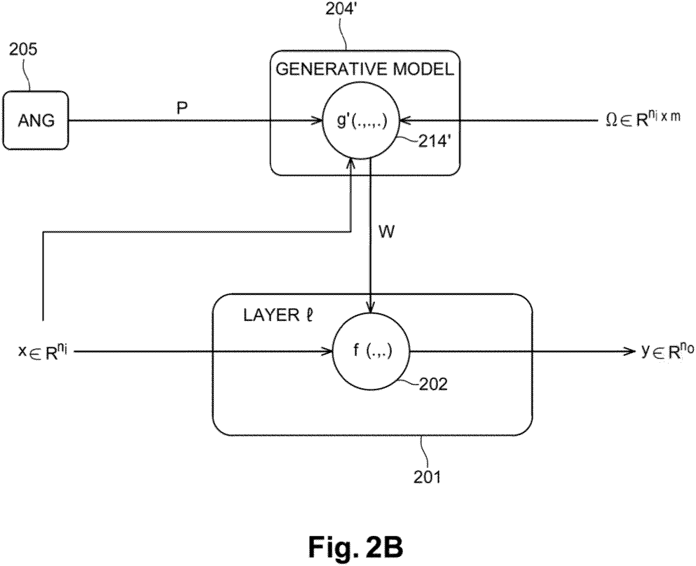

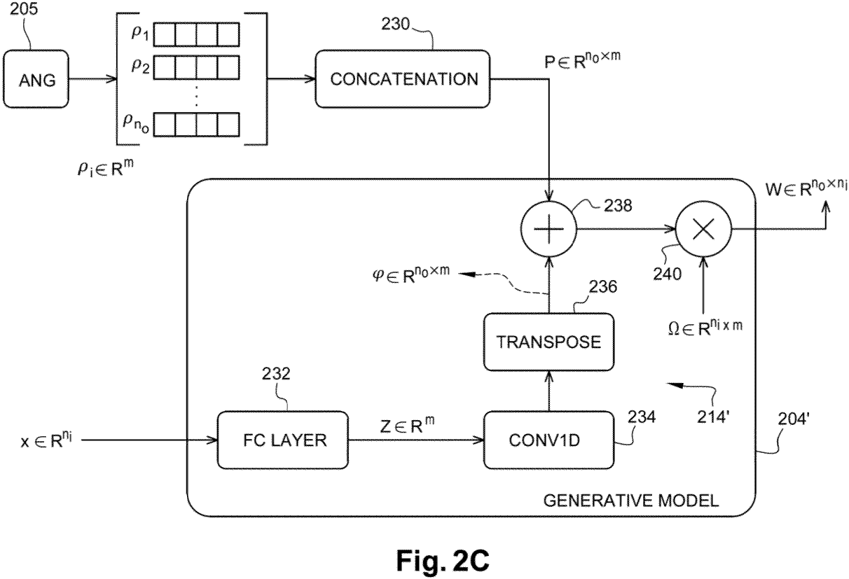

FIG. 2A shows an example of a hardware implementation of a dense layer of a deep neural network according to an example of embodiment of the present disclosure.

In particular, FIG. 2A illustrates a deep neural network comprising a dense layer 201 (LAYER 1) configured to generate output data y by applying a layer operation 202 (f(. , .) ) on input data x and weights W. As an example, the input data x ∈ R^{x1} of layer 201 form a vector of size nᵢ and the output data y ∈ R of layer 201 form a vector (y₁,y₂, ···,yᵢ,yᵢ₊₁,···,y_{n₀} of size n₀. In certain cases, output data y are stored in a volatile or non-volatile memory (OUTPUT MEM) 203. As an example, when output data y are supplied as input data to one or a plurality of next layers, their storage is performed in volatile fashion and memory 203 is for example a register. The matrix of weights W enabling the generation of the n₀ coordinates of vector y would then be of size nₜ by n₀.

In the described embodiments, instead of storing the matrix of weights W in a memory, the implementation of an auxiliary generative neural matrix 204 (GENERATIVE MODEL) is provided to generate weights W column by column or row by row.

Auxiliary network 204 is for example an autoencoder of U-net type, or any other type of generative network. Further, auxiliary network 204 is coupled to a number generation circuit 205 (ANG) such as, for example, a pseudo-random number generator or a cellular automaton.

Number generator 205 is configured to generate vectors of size m, where m is an integer smaller than n₀. According to an embodiment, a vector ρᵢ 207 is generated by generator 205 and is for example stored in a register 209 (REGISTER). Vector 207 is then supplied to auxiliary network 204. Auxiliary network 204 further receives a matrix Ω ∈ R^{nᵢ×m} of size n₁ by m , for example stored in a non-volatile memory 211 (NV MEM). Matrix Ω is a matrix of weights for auxiliary network 204, this matrix Ω having been previously learnt.

In embodiments, number generator circuit 205, for example, a pseudo-random number generator circuit, is implemented in or near memory 211. Memory 211 is for example a SRAM (static random access memory) matrix. The implementation near or in memory matrix 211 enables to perform the computing directly in memory 211 (“In Memory Computing”) or near memory 211 (“Near Memory Computing”). The numbers are then generated, for example, based on one or a plurality of values stored at first addresses in the memory, and stored at second addresses in the memory, without passing through a data bus coupling the memory to circuits external to the memory. For example, number generator 205 is a linear feedback shift register (LFSR) which is implemented in or near memory matrix 211.

The different possible implementations of a number generator are known and are within the abilities of those skilled in the art.

According to an embodiment, number generator 205 is configured to generate, at each start-up, always the same sequence of vectors. In other words, auxiliary neural network 204 always manipulates the same vector sequence. As an example, if number generator 205 is a pseudo-random number generator, the seed used is a fixed value and, for example, stored in memory 211.

According to an embodiment, during a learning phase of auxiliary neural network 204, the vector sequence used, for example, for the learning of matrix Ω, is the same sequence as that used, afterwards, in the inference operations and to generate weights W.

According to an embodiment, the vectors forming the vector sequence are generated so that the correlation between vectors is relatively low, and preferably minimum. Indeed, the correlation between two vectors ρᵢ and ρⱼ, 1 ≤ i,j ≤ n₀, induces a correlation between outputs yᵢ and yⱼ. As an example, the initialization, or the selection of the seed, of number generator 205 is performed to introduce the least possible correlation between the vectors of the vector sequence. The initialization of a number generator is known by those skilled in the art who will thus be able to configure number generator 205 to decrease or minimize any correlation in the vector sequence.

According to an embodiment, auxiliary network 204 generates an output vector Wᵢ= (W_{i,1}W_{i,2},···,W_{i,nᵢ}) of size nᵢ by applying a function or a kernel 214 g(.,.) taking as variables matrix Ω and the generated vector 207 ρᵢ. As an example, function g is linear and corresponds to multiplication Ωρ_{i.} In another example, a non-linear function, for example, an activation function σ, is additionally applied to value Ωρᵢ. An example of non-linear function g is defined by g(Ω, ρ) = σ(Ωρ) where σ is itself a non-linear function such as, for example, σ(u) = u1_{[0,1]}(u) with 1_{[0,1]}(.) the function indicative of interval [0,1].

Generally, it will be said hereafter of function g that it is linear if it is cascaded by a linear function σ, such as for example the identity function. In other words, function g is linear if g(Ω, ρ) = λΩρ, where λ is a real number, and non-linear if g(Ω,ρ) = σ(Ωρ), with σ non-linear. Similarly, it will be said of f that it is linear or non-linear under the same conditions.

Output vector W₁ is then for example temporarily stored in a memory, for example, a register 217. Vector W₁ is then transmitted to the dense layer 201 of the deep neural network which applies layer operation 202 f(.,.) to vector W₁ and to input vector x to obtain the i-th coordinates 215 y₁ of the output vector y. Thus, one has relation:

$${y}_{i} = f \left(g \left(\text{Ω,} {\text{ρ}}_{1}\right) , x\right) .$$

As a result of the generation of coordinate y₁ 215, number generator 205 generates a new vector ρᵢ₊₁ 219 which is then for example stored in register 209, overwriting the previously-generated vector ρᵢ 207. The new vector pᵢ₊₁ 219 is then transmitted to auxiliary network 204 to generate a new vector 221 Wᵢ₊₁ = (W_{i+1,1}Wᵢ₊_{1,2} Wᵢ₊₁). The generation of vector 221 is performed by applying the same function g to vector ρᵢ₊₁ 219 and to matrix Ω. Vector Wᵢ₊₁ 221 is then for example stored in register 217, for example, overwriting vector Wᵢ 213.

Vector Wᵢ₊₁ 221 is then transmitted to layer 201 of the deep neural network, which generates the i+1-th coordinate yᵢ₊₁ 223 of the output vector y by applying operation 202 to vector Wᵢ₊₁ 221 as well as to input vector x. As an example, when function g is defined by g(Ω, ρ) = σ(Ωρ) and when function f is defined by f(W , x) = W^{T} x, where W^{T} represents the transpose matrix of W, output vector y is represented by:

$$y = \left[\begin{matrix}\text{σ} {\left(\text{Ω} {\text{ρ}}_{1}\right)}^{T} \\ ⋮ \\ \text{σ} {\left(\text{Ω} {\text{ρ}}_{{n}_{\text{c}}}\right)}^{T}\end{matrix}\right] x .$$

Each of the n₀ coordinates of output vector y is thus generated based on input vector x of size nᵢ and on a vector of size n_{i·} This enables for only matrix Ω to be stored in non-volatile fashion, and its size is smaller than nᵢ × n₀, since m is smaller than n_{0·} The matrix of weights for dense layer 201 is generated row by row from matrix Ω containing mnᵢ coefficients. Each row of weights is preferably suppressed, or in other words not kept in memory (in register 217) after its use for the generation of the corresponding coordinate of output vector y, to limit the use of the memory as much as possible. The compression rate CR of this embodiment is then equal to

$$\frac{m {n}_{i}}{{n}_{i} {n}_{o}} = \frac{m}{{n}_{e}} .$$

The compression rate CR is all the lower as m is small as compared with n_{0·}

In the previously-described embodiment, the successive vectors Wᵢ supplied at the output of the generative model correspond in practice to the rows of matrix W^{T}. Each new vector Wᵢ, enabling to compute a value yᵢ implies performing nᵢ MAC (“Multiplication ACumulation”) operations. A MAC operation generally corresponds to the performing of a multiplication and of an “accumulation” equivalent in practice to an addition. In practice, the calculation of a value yᵢ may be performed by an elementary MAC computing device capable of performing an operation of multiplication between two input operands and to sum the result with a value present in a register and to store the summing result in this same register (whereby the accumulation). Thus, if an elementary MAC calculator is available, the calculation of a value yᵢ requires successively performing nᵢ operations in this elementary MAC. An advantage of such a solution is that it enables to use a very compact computing device from the hardware point of view, by accepting to make a compromise on the computing speed, if need be.

According to an alternative embodiment, the successive vectors Wᵢ correspond to the columns of matrix W^{T}. In this case, values (y₁,y₂,···,yᵢ,yᵢ₊₁,···,y_{n₀} can then be calculated in parallel by using n₀ MAC calculators. Each new vector Wᵢ thus powering the calculation of a MAC operation in each MAC calculator. An advantage of this solution is that it enables to carry out more rapidly (n₀ times more rapidly) the general MAC calculation operations, at the cost of more significant hardware. The memory need, particularly for vectors Wᵢ remains identical to the previous embodiment.

According to another alternative embodiment, the vectors Wᵢ successively delivered by generative model 204 are temporarily stored in a memory enabling to integrate them all. The calculation of values (y₁,y₂,···,yᵢ,yᵢ₊₁,···,y_{n₀} is then performed “once” for example by means

$$\left({y}_{1} , {y}_{2} , ⋯ , {y}_{i} , {y}_{i + v} ⋯ , {y}_{{n}_{\text{o}}}\right)$$

of a hardware accelerator dedicated to this type of operations (matrix product, matrix × vector). This hardware accelerator may possibly be provided to integrate the other devices and method steps of the present invention, for example by integrating the memory storing matrix Ω,by integrating the computing means enabling to implement the generative model, and/or by integrating the random number generator.

FIG. 2B illustrates another example of implementation of a dense layer of a deep neural network according to an embodiment of the present disclosure. In particular, the deep neural network is similar to that shown in FIG. 2A, except that auxiliary neural network 204 is replaced with an auxiliary neural network 204′ configured to apply a function or a kernel 214′ g′(.,.,.) Function or kernel 214′ takes, as an input, input vector x, in addition to the variables of matrix Ω , and auxiliary neural network 204′ is thus a dynamic network. Indeed, the matrix W, generated by the neural network 204′, depends on the input vector x, whereas the vectors ρᵢ model an a priori information on the parameters of the matrix W. The operations on the input vector x allows to take into account the properties on the input vector x and to adjust, in a dynamical fashion, the behavior of the layer 201 via the matrix W. Conversely to function or kernel 214, function or kernel 214′ takes as an input the n₀ vectors ρᵢ, to p_{n₀}_, all of size m. As an example, the n₀ vectors are concatenated in the form of a matrix P of size n₀ × m. The output of auxiliary neural network 204′ is then a matrix W of size n₀ × nᵢ . The generated matrix W then is for example transmitted to the dense layer 201 of the deep neural network which applies a layer operation to matrix W and to input vector x to generate an output vector y of size n_{0·} For example, the matrix W is provided column by column to the layer 201.

FIG. 2C illustrates an example of implementation of a dynamic auxiliary neural network 204′.

As an example, vectors ρ₁ to ρ_{n₀} are concatenated (CONCATENATION), for example, in a register 230. The concatenation results in a matrix P of size n₀ × m. According to an embodiment, input vector x of size nᵢ is supplied to network 204′ and more particularly to a layer 232 (FC LAYER) of network 204′. As an example, layer 232 is a fully connected layer. Layer 232 is configured to generate a vector z ∈ R^{m} of size m, based on input vector x . Vector z is then transmitted to a one-dimensional convolutional layer 234 (CONV1D). The one-dimensional convolution operation generates for example n₀ output channels. As an example, the one-dimensional convolution further comprises the addition of each vector sequence ρᵢ with an output channel i, i ∈ {1, ..., n₀}. Thus, the matrix W is furnished column by column to the layer 201. As an example, layer 234 applies n₀ convolution filters, each filter being of size k, to input vector x , k being for example a parameter corresponding to the size of filters, or windows, used during the one-dimensional convolution operation. As an example, k is equal to 3 or 5 or 7 or 9 or 11, etc. Layer 234 generates a two-dimensional tensor of size m × n₀ which is for example transposed, for example by an operation 236 (TRANSPOSE), to obtain a two-dimensional tensor φ of same size as matrix P, that is, of size n₀ × m.

Matrix P is for example transmitted to network 204′ and is added to tensor φ, for example, by an adder 238. The output of adder 238 is for example supplied to a circuit 240 configured to implement a multiplicative operation. Circuit 240 further receives the matrix of weights and then generates matrix W. As an example, circuit 240 is implemented in, or near, memory 211 where matrix Ω is stored.

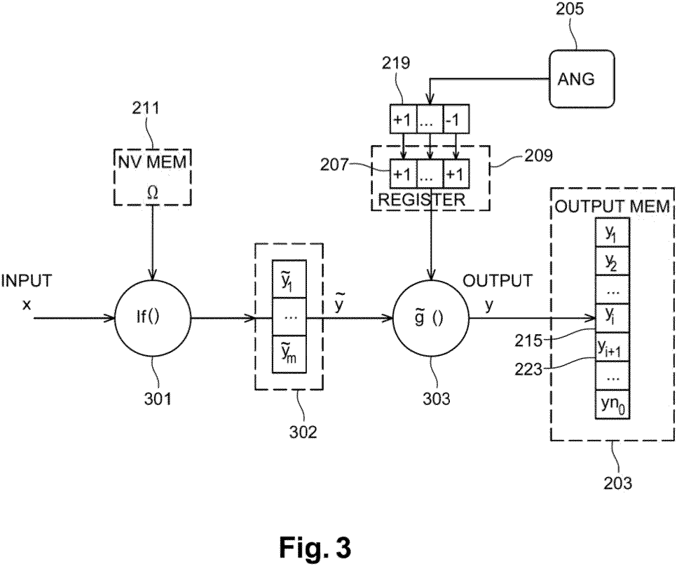

FIG. 3 illustrates an example of implementation of a deep neural network according to another embodiment capable of being used in a design method according to the present disclosure. In particular, FIG. 3 illustrates an example of implementation when the two operations or kernels f and g are entirely linear, in other words the activation function σ applied to the result of the matrix multiplication is itself linear, such as for example the identity function. In the example where function σ is the identity function, the order of operations g and f may be inverted. Indeed, in this case, one has the relation:

$$y = \left[\begin{matrix}{ρ}_{1}^{T} \\ ⋮ \\ {ρ}_{{n}_{o}}^{T}\end{matrix}\right] {Ω}^{T} x .$$

In this formulation, input vector x is first compressed towards a vector of dimension m by applying thereto a function 301 lf, a variable of which is matrix Ω, and which is defined by lf (Ω, x) = Ω^{T}x. The result of operation 301 on input data x is a vector ỹ = (ỹ₁,^{...}, ỹₘ)of size m and is for example temporarily stored in a memory 302. Vector ỹ is then sequentially projected by the n₀ vectors of size m generated by number generator 205 to obtain output data y. In other words, once vector ỹ has been obtained, number generator 205 generates vector ρᵢ 207, and the i-th coordinate 215 yᵢ of the output vector y is obtained by applying an operation 303 g̃ defined by

$$\tilde{g} \left({\text{ρ}}_{i} , \tilde{y}\right) = {\text{ρ}}_{i}^{T} \tilde{y} .$$

The i+1-th coordinate yᵢ₊₁ 223 of vector y is then obtained in the same way, from the new vector 219 ρᵢ₊₁ generated by generator 205.

The number of MACs (“Multiplication Accumulation”) used for the operation of a standard dense layer is n₀nᵢ. The number of MACs used for the operation of the dense layer 201 described in relation with FIG. 2A is for example n₀mnᵢ + nᵢn₀, which is higher than the number of MACs of a standard dense layer. Additional term nᵢn₀ is due to auxiliary network 204. However, the number of MACS is decreased to mnᵢ + mn₀ when operation g is cascaded by a linear activation function and when the implementation described in relation with FIG. 3 is implemented. The ratio MR of the number of MACs used by the implementation described in relation with FIG. 3 to the number of MACs used by a standard dense layer is:

$$M R = \frac{m {n}_{i} + m {n}_{0}}{{n}_{i} {n}_{0}} = \frac{m}{{n}_{0}} + \frac{m}{{n}_{i}} .$$

Ratio MR is then smaller than 1 when integer m is appropriately selected, for example when

$$m < m i n \left({n}_{0} , {n}_{i}\right) / 2.$$

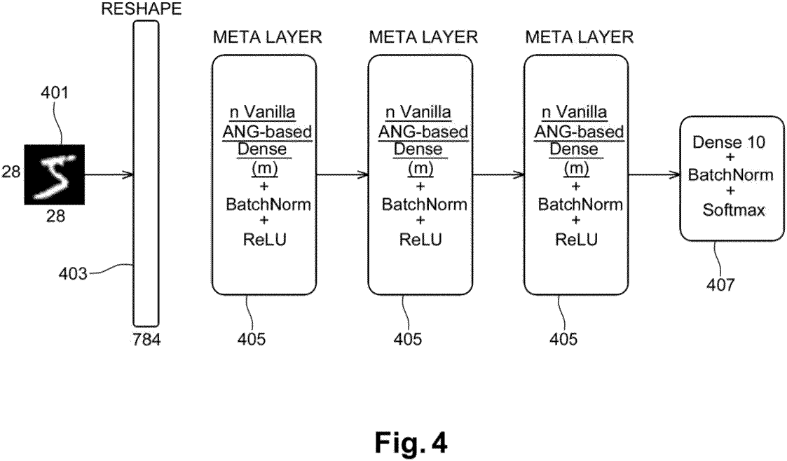

FIG. 4 illustrates an example of model of a deep neural network comprising dense layers as illustrated in FIGS. 2A, 2B, or 3.

In particular, FIG. 4 shows an example of implementation of a network comprising dense layers, as described in relation with FIGS. 2A or 2B of with FIG. 3, and calibrated based on data MNIST containing representations of handwritten numbers. An image 401 of 28 pixels by 28 pixels, for example representing number 5, is supplied to the input of the deep neural network. Image 401 is a pixel matrix, each pixel being for example shown over 8 bits. Thus, for example, image 401 may be represented in the form of a matrix of size 28 by 28 having each coefficient equal, for example, to an integer value between and including 0 and 255. Image 401 is then reshaped (RESHAPE) in a vector 403 of size 784. As an example, the 28 first coefficients of vector 403 represent the 28 coefficients of the first column or row of the matrix representation of image 401, the 28 second coefficients of vector 403 represent the 28 coefficients of the second column or row of the matrix representation of image 401, and so on.

Network 200 then consecutively applies three meta layers 405 (META LAYER) each formed, in this order, of a number n of dense layers 201 operating, each, in combination with an auxiliary network 204 such as described in relation with FIG. 2A and referenced as being so-called “Vanilla ANG-based Dense(m)” layers. In each meta-layer 405, the n “Vanilla ANG-based Dense(m)” layers are followed by a “Batch Normalization” layer (BatchNom), and then by a layer ReLU. An output layer 407 comprises, for example, the application of 10 successive standard dense layers, and then of a Batch Normalization layer and of a classification layer Softmax generating a probability distribution. As an example, the output of layer 407 is a vector of size 10, having its i-th coefficient representing the probability for input image 401 to represent number i, i being an integer between 0 and 9. The output data of the network is for example the number having the highest probability.

The size and the complexity of the deep neural network thus described depends on the number n of “Vanilla ANG-based Dense(m)” layers and on the length m of the vectors generated by generator 205 on these layers.

According to an embodiment, the non-linear function σ used for each “Vanilla ANG-based Dense(m)” layer is an activation function Softsign h defined by:

$$h \left(x\right) = \frac{x}{\left|x\right| + 1} .$$

The method thus described in relation with FIG. 4 has been tested and has a high performance. In particular, the model has been trained 5 different times with parameters n = 256 and m = 16 by using an Adam optimizer and a binary cross-entropy loss function and with a learning rate of 10⁻³ during the 50 first iterations of the learning (or epochs) and then decreased by a factor 0.1 every 25 iterations until the total completion of the 100 iterations. A group of 100 data (batch) has been used for each iteration. The number generator 205 used generated numbers according to a centered and reduced normal law. As a result of the 5 trainings, the average accuracy for the model described in relation with FIG. 4 is 97.55% when function σ is linear and 97.71% when function σ is replaced by the Softsign activation function.

The same training has been performed on a network as described in FIG. 4, but for which the 256 “Vanilla ANG-based Dense(16)” layers have been replaced with 29 standard dense layers. In this case, the average accuracy was only 97.27%.

The average accuracy of the models, as well as the number of parameters and of MACs used, are summed up in the following table:

TABLE 1

| | Vanilla ANG-based Dense + Softsign (n=256, m=16) | Vanilla ANG-based Dense (n=256, m=16) | Standard dense (n=29) | Standard dense (n=256) |
|---|---|---|---|---|
| Accuracy | 97.71% | 97.55% | 97.27% | 98.58% |
| Number of parameters | 24,852 | 24,852 | 24,902 | 335,892 |
| Number of MACs | 5,642,752 | 36,362 | 24,805 | 335,114 |

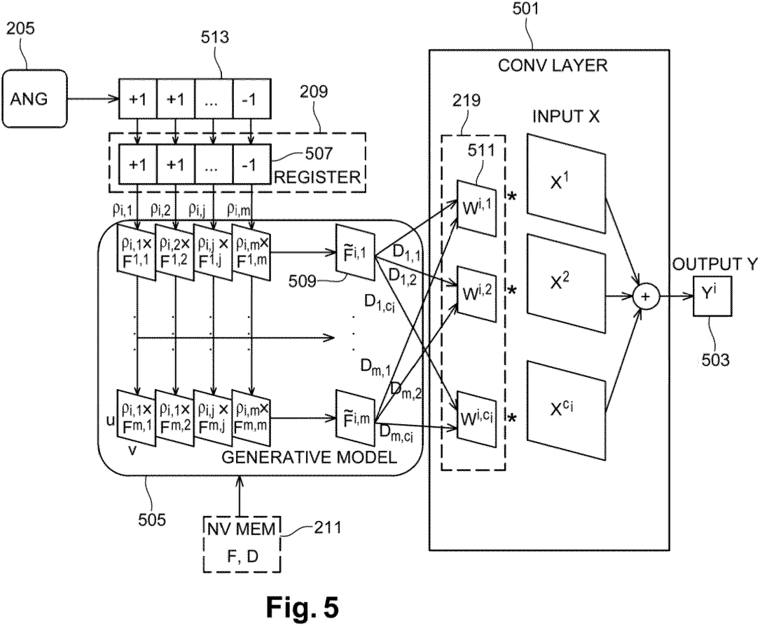

FIG. 5 illustrates an example of implementation of a convolutional layer 501 (CONV LAYER) of a deep neural network according to an embodiment of the present disclosure.

Convolutional layer 501 takes input data, which are for example characterized as being an element X ∈ R^{hᵢ×wᵢ×cᵢ} (INPUT X), and generates output data Y ∈ R^{h₀×w₀×c₀} (OUTPUT Y).

Integers cᵢ and c₀ correspond to the number of channels of the input data and of the output data. In the case where the input and output data are images, the channels are for example channels of colors such as red, green, and blue. Integers hᵢ, h₀, wᵢ, and w₀ for example respectively represent the widths and heights in pixels of the input and output images.

The implementation of a standard convolutional layer provides the use of a weight model W ∈ Rto generate output data Y based on input data X. Element W then decomposes into c₀ convolution kernels Wⁱ ∈ {1,..., c₀}and each kernel Wⁱ comprises cᵢ convolution filters W^{i,j}, j ∈ {1, ... , c_{i},}of dimension u × v, where u and v are integers. The i-th channel Yⁱ 503 is then obtained as being the convolution product between input data X and convolution kernel Wⁱ. In other words,

$${Y}^{i} = {\sum }_{j = 1}^{{c}_{i}} {x}_{j} \times {W}^{i , j} .$$

The number of parameters stored in a volatile or non-volatile memory, for the implementation of such a convolutional layer, then is the size of element W , that is, uvcᵢc₀ and the number of MACS used is h₀w₀c₀uvcᵢ. When the number of input and output channels cᵢ and c₀ is high, the required memory resources and computing resources are significant.

In the embodiments described in relation with FIG. 5, instead of storing element W in a memory, the implementation of an auxiliary generative neural network 505 (GENERATIVE MODEL) to generate convolution kernels W one after the others is provided.

As described in relation with FIGS. 2 and 3, the device having convolutional layer 501 implemented thereon comprises a number generator 205 (ANG) configured to generate vectors ρ of size m, where integer m is smaller than value c_{0·} According to an embodiment, number generator 205 is a cellular automaton configured to only generate vectors having coefficients at values in {-1,1}. Number generator 205 is further coupled to a generative neural network 505 (GENERATIVE MODEL). As an example, generator 205 generates a vector ρᵢ 507 and for example stores it in register 209. Vector ρᵢ 507 is then supplied to auxiliary neural network 505. Auxiliary network 505 is then configured to generate a set of m resulting filters P̅ⁱ,formed of a number m of filters of size u by v, based on vector ρᵢ and of a set F of m × m two-dimensional filters F^{k,h}, where k ∈ {0, ··· , m} and h ∈ {1, ... ,m}. Set F is for example stored in non-volatile memory 211.

To generate set P̅ⁱ, each filter F^{k,h} of set F, k = 1, ... , m and h = 1, ... , m, is multiplied by the h-th coefficient ρ_{i,h} of vector ρ_{i·} A first resulting filter F̅^{i,1} 509 is then defined by:

$${\overline{F}}^{i , 1} = {\text{σ}}_{1} \left({\sum }_{h = 1}^{m} {F}^{1 h} {\text{ρ}}_{i , h}\right) .$$

where σ₁ is an activation function, such as a non-linear function independently applied on each element (“element-wise”) or a normalization operation, such as a layer-wise operation or group-wise operation or any type of other non-linear operation. Generally, a k-the resulting filter, k = 1,... m, F̅^{i,k} is defined by:

$${\overline{F}}^{i , k} = {\text{σ}}_{1} \left({\sum }_{h = 1}^{m} {F}^{k , h} {\text{ρ}}_{i , h}\right) .$$

The m filters

$${\tilde{F}}^{i , k} , k = 1 , ... , m$$

are then for example combined by network 505 as if they were input data of a standard dense layer. A weight matrix

$$D = {\left({D}_{k , h}\right)}_{\begin{matrix}1 \leq k \leq m \\ 1 \leq h \leq {c}_{i}\end{matrix}}$$

of m by cᵢ size is for example stored in non-volatile memory 211 and is supplied to auxiliary network 505 to obtain the cᵢ filters wⁱ for convolutional layer 501. A first filter w^{i,1} 511 is for example defined by:

$${W}^{i , 1} = {\text{σ}}_{2} \left({\sum }_{k = 1}^{m} {\tilde{F}}^{i , k} {D}_{k , 1}\right) .$$

where o₂, is an activation function, such as a non-linear function or a normalization function, such as a layer-wise or group-wire operation or any type of other non-linear operation. Generally, an h-th filter w^{i,h}, h = 1, ...c₁, is for example defined by:

$${W}^{i , h} = {\text{σ}}_{2} \left({\sum }_{k = 1}^{m} {\tilde{F}}^{i , k} {D}_{k , h}\right) .$$

The c₁ filters W¹ are then for example stored in register 219 and supplied to convolutional layer 501. Layer 501 generates by convolution an output image Y^{t}, of size h₀ by w₀ pixels, based on the c₁ input images x¹, x², ....X^{c1}, of size h₁ by w₁ pixels. In other words, Y¹ corresponds to the channel 1 of output image Y and is defined by:

$${Y}^{i} = {\sum }_{h = 1}^{{c}_{i}} {X}^{k} \times {W}^{i , h} .$$

Generator 205 then generates a new vector ρ₁₊₁ 513, that it stores, for example, in register 209 at least partially overwriting vector ρ₁ 507. Vector 513 is then supplied to generative network 505 to generate c₁ new filters Wⁱ⁺¹ which are for example stored in memory 219, at least partially overwriting filters W¹. The new filters Wⁱ⁺¹ are then transmitted to convolutional layer 501 to generate output channel Y¹⁺¹. The generator thus generates, one after the others, cₒ vectors of size _{m,} each of these vectors being used to obtain c₁ filters for convolutional layer 501. A number cₒ of channels for output image Y are thus obtained.

According to this embodiment, all the filters W of layer 501 are generated from auxiliary network 505 with m²uv + mc₁ parameters, mc₁ being the number of coefficients of matrix D and m² uv being the number of coefficients characterizing the set of filters F. The required number of MACs then is (uvm² + uvc₁m + h₀w₀uvc₁)c₀, which is higher than the number of MACs used for the implementation of a standard convolutional layer. Indeed, the ratio MR of the number of MACs for the embodiments described in relation with FIG. 5 to the number of MACs for a standard implementation is

$$M R = 1 + \frac{{m}^{2}}{{h}_{o} {w}_{o} {c}_{i}} + \frac{m}{{h}_{o} {w}_{o}}$$

, which is greater than 1. However, the fact of using auxiliary network 505 to generate kernel W significantly decreases the size of the memory which would be used in a standard implementation. Indeed, the ratio CR between the number of parameters stored for the implementation of a convolutional layer according to the present description and the implementation of a standard convolutional layer can be expressed as

$$C R = \frac{{m}^{2} u v + m {c}_{1}}{u v {c}_{i} {c}_{0}} = \frac{{m}^{2}}{{c}_{i} {c}_{0}} + \frac{m}{u v {c}_{0}}$$

. The value of m is for example smaller than c₁ as well as than c₀, and this ratio is thus smaller than 1.

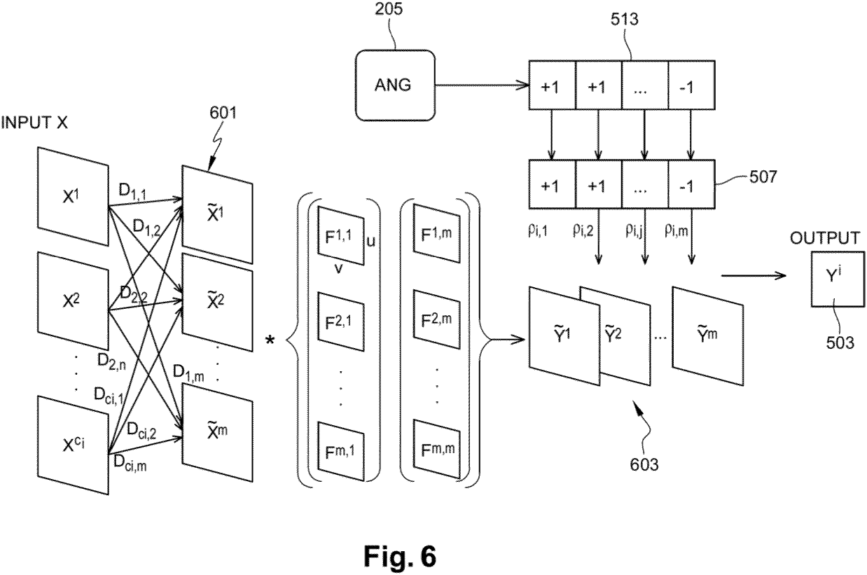

FIG. 6 illustrates another example of implementation of a convolutional layer according to an embodiment of the present disclosure. In particular, FIG. 6 illustrates an example of implementation when functions σ₁ and σ₂ are linear, for example σ₁ and σ₂ are the identity function. In this case, the number of MACs used can be decreased.

According to an embodiment, the number c₁ of channels of input data X is decreased in a number m of channels 601 X̅¹,X̅², . ,X̅^{m}. In particular, each new channel X̅^{k}, k = 1, ... m, is defined by:

$${\tilde{\text{X}}}^{\text{k}} = {\sum }_{j = 1}^{{c}_{1}} {D}_{k , j} {X}^{i} .$$

The m new channels are convolved with the filters of set F to obtain m new channels Y^{h} 603, h = 1, ...,m. Each new channel Y^{h} is defined by:

$${\tilde{Y}}^{h} = {\sum }_{k = 1}^{m} {F}^{k , h} \times {\tilde{X}}^{k} .$$

The i-th output channel 503 is then generated based on channels Y^{h}, h = 1, ...,m, and based on a vector ρ₁, for example, vector 507, generated by number generator 205. The i-th output channel Y¹ 503 is then defined by:

$${Y}^{i} = {\sum }_{h = 1}^{m} {\text{ρ}}_{i , h} {\tilde{Y}}^{h} .$$

Generator 205 then generates a vector ρ₁₊₁, for example, vector 513, based on which the i+1-th output channel Y¹⁺¹ is obtained as a linear combination of the coefficients of vector ρ₁₊₁ and of channels Y^{h} 603, h = 1, _{...,}m, already calculated.

The number of MACs used for the implementation described in relation with FIG. 6 is h₀w₀mc₁ + h₀w₀m²uv + h₀w₀c₀m. Thus, the ratio MR of the number of MACs used for the implementation described in relation with FIG. 6 to the number of MACs used for the implementation of a standard convolutional layer is

$$M R = \frac{m}{u v {c}_{o}} + \frac{{m}^{2}}{{o}_{i} {c}_{o}} + \frac{m}{u v {c}_{i}} .$$

This ratio is smaller than 1 when integerm is appropriately selected, for example, taking m ≤ min(c_{o,}_{cj}).

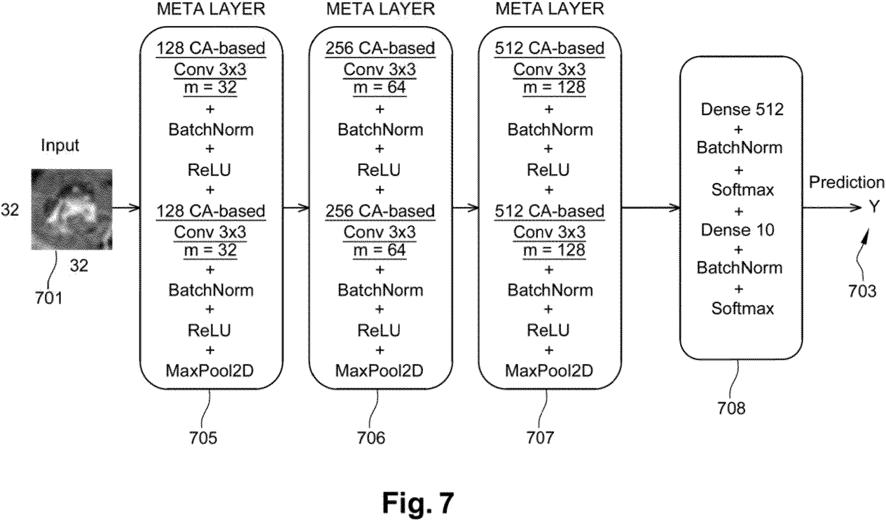

FIG. 7 is an example of a model of a deep neural network comprising convolutional layers such as illustrated in FIG. 5 or in FIG. 6.

In particular, FIG. 7 shows an example of a deep neural network comprising convolutional layers such as described in relation with FIGS. 5 and 6 and calibrated from database CIFAR-10 containing images belonging to ten different classes. Each class (planes, cars, birds, cats, deer, dogs, frogs, horses, boats, and trucks) is represented by 60,000 images of 32 by 32 pixel sizes and described by 3 color channels (red, green, and blue). An image 701 of the database, in this example showing a frog, is supplied an input data to a deep neural network formed of a plurality of convolutional layers having their implementation described in relation with FIGS. 5 or 6. The neural network aims at delivering a prediction 703 of the class to which the image belongs. For example, the expected output data are the character string “frog”.

The convolutional layers of the neural network operate in combination with an auxiliary network 505 such as described in relation with FIGS. 5 or 6 and are referenced as being “CA-based Conv(m)” layers. In the implementation illustrated in FIG. 7, the filters of set F and the coefficients of matrix D and binarized and generator 205 is a cellular automaton configured according to rule 30 of after classification in the Wolfram table as known in the art, and having a random initialization.

The described neural network applies three meta-layers 705, 706, and 707 (META LAYER), each formed, in this order, of a number n of “CA-based Conv(m) 3x3” layers optionally followed by a “Batch Normalization” layer, corresponding to the non-linear normalization of convolutional layers 501, provided by function σ₂, of a layer ReLU, of a new “CA-based Conv(m) 3x3” layer followed by a new “BatchNorm” and by a new ReLU layer. Meta-layers 705, 706, and 707 each end with a “MaxPool2D” layer.

The number n of convolutional layers in meta-layer 705 is n=128 and the parameter m associated with each layer is m=32. The number n of convolutional layers in metal-layer 706 is n=256 and the parameter m associated with each layer is m=64. Finally, the number n of convolutional layers in meta-layer 707 is n=512 and the parameter m associated with each layer is m=128.

Output layer 708 comprises the application of a dense layer of size 512, of a “BatchNorm” layer, of a Softmax classification layer, and of a new dense layer of size 10. As an example, the output of layer 708 is a vector of size 10, the 10 corresponding to the 10 classes of the database. Layer 708 then comprises a new “BatchNorm” layer and then a new Softmax layer. The output data of the network is for example the name of the class having the highest probability after the application of the last classification layer.

The model thus described in relation with FIG. 7 has been tested and trained by using an Adam optimizer over 150 iterations (or epochs). A 10⁻⁸ learning rate is set for the 50 first iterations of the learning, then is decreased by a factor 0,1 every 25 iterations until the total completion of 150 iterations. A group of 50 data (batch) is used for each iteration. After the training, the average accuracy for the model described in relation with FIG. 5 was 91.15%. When the “CA-based Conv(m)” layers are followed by an additional normalization layer corresponding to the application of function σ₂, as a function of normalization of each of kernels Wⁱ, the average accuracy was as high as 91.26%. In the case where the convolutional layers are standard convolutional layers, that is, convolutional layers which are not combined with a number generator, the average accuracy was 93.12%. However, the memory used for such an implementation was almost 400 times greater than for the two previous implementations.

The average accuracy of the models, as well as the number of parameters and of MACs used, are summed up in the following table:

TABLE 2

| | CA-Based Conv (without BatchNorm) | CA-Based Conv (without BatchNorm) | Standard Conv |
|---|---|---|---|
| Accuracy | 91.26% | 91.15% | 93.12% |
| Memory | 0.37 Megabytes | 0.37 MegaBytes | 146 MegaBytes |
| Number of MACs | 1299 | 99 | 608 |

All the previously described examples of embodiment describe the operation of a neural network comprising at least one layer implementing a method of generation of the parameters of this neural layer corresponding to the parameter values predefined, or more exactly previously learnt due to a learning method. As known per se, a learning method of a neural network comprises defining the values of the parameters of the neural network, that is, defining the values of the parameters essentially corresponding to the weight of the synapses. The learning is conventionally performed by means of a learning database comprising examples of corresponding expected input and output data.

In the case where the neural network integrates a neuron layer (Layer 1) 201 such as described in relation with FIG. 2A, the learning of this neuron layer 201 may be performed in several ways.

A way of performing the learning comprises first learning the values of the parameters of matrix W^{T} without considering the generation of these parameters by the generative model, by carrying out a conventional learning method of the general neural network by an error back-propagation method (from the output of the network to the input). Then, the learning of the parameters of generative model 204 is carried out (by defining Ω) with as a learning database a base formed on the one hand of a predefined sequence of vectors (ρ) intended to be generated by generator ANG 205 (based on a predefined “seed”) during an inference sequence and on the other hand of the vectors Wᵢ respectively expected for each of vectors ρ₁. An advantage of this first way of performing the learning is potentially its greater simplicity of calculation of the parameters. However, it is possible for this method in two steps to lead to introducing imperfections in the generation of the values of matrix W^{T} during subsequent inferences (in phase of use of the neural network).

Another way of performing the learning comprises learning the parameters of generative model 204 at the same time as the learning of the parameters of matrix W^{T} by performing an error back-propagation all the way to matrix Ω. It is indeed possible to use an optimization algorithm (such as an error back-propagation) all the way to the values of Ω, knowing on the one hand the expected output of the main network, its input as well as the predefined sequence of vectors (ρ) intended to be generated by generator ANG 205 (based on a predefined “seed”) during an inference sequence.

It should be noted that in all the previously-described examples, the parameters of the neuron layer which are desired to be defined (the parameters of matrix Ω in practice) correspond to values of parameters of a neuron network having a topology which is previously defined. The topology of a neural network particularly enables to define, for each neuron layer, the type and the number of synapses coupled to each neuron. Generally, to define a topology of a neural network, it is spoken of meta-parameters of this neural network. Thus, in the previously described examples, the meta-parameters appear in the definition of functions f and g. These functions respectively include a transition matrix W and Ω. The previously discussed parameters (in the different examples) thus correspond to given (learnt) values of transition matrices Ω and W.

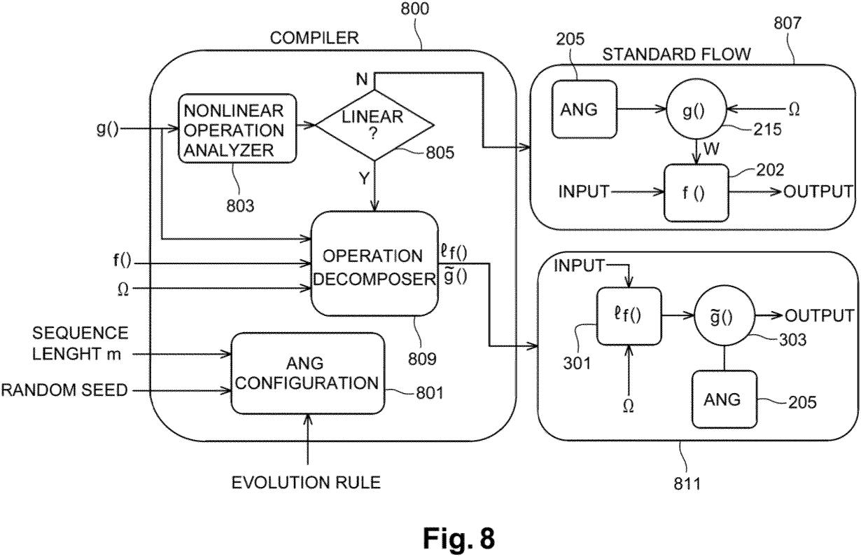

FIG. 8 is a block diagram illustrating an implementation of a compiler 800 (COMPILER) used for the operation of circuit design allowing the hardware implementation of a neural network such as described in relation with FIGS. 2, 3, 4, 5, or 6.

Compiler 800 comprises a step of determination of the desired configuration 801 (ANG CONFIGURATION) of number generator 205. The number generator configuration is for example that of a cellular automaton or that of a pseudo-random number generator. By configuration of the generator, there is meant the definition of its topology, for example, the number of latches and/or logic gates, of feedback connections, of a generator. Number generator 205 is capable of generating a sequence of numbers from a seed (RANDOM SEED), from an indication of the dimension of each generated vector (SEQUENCE LENGTH m), and from a rule (EVOLUTION RULE), these three elements being specified at the compiler input. When number generator 205 is a linear congruential generator, the rule is for example the algorithm used by congruential generator 205, such as, for example, the “Minimum standard” algorithm. In another example, number generator 205 is a linear feedback shift register implemented in hardware fashion. The desired configuration of the number generator may be achieved by an optimal topology search by minimizing a predefined cost function capable for example of taking into account factors such as the bulk, the random number generation speed, etc. The optimal topology implementing the specified constraints (m; random seed; evolution rule) may be searched for in a circuit topology database by comparing the performances of the different topologies once customized to the specified constraints.

Compiler 800 may be used to analyze specifications given to implement a layer of a neural network such as defined, or also modeled, by the generic representation illustrated in FIG. 2A. The data at the compiler input then are a topology of the neural network defined in particular by functions g and f as well as a matrix of parameters Ω. The compiler then performs a set of analysis operations based on these input specifications, and may possibly also considering the specifications given for the random numbe generator. To ease the implementation of the analysis operations carried out by the compiler, the supply of functions g and f may be achieved in the form of a mathematical combination of predefined library functions, in relation for example with the different topologies that can be envisaged for the implementation of the neural network.

The compiler is then provided to perform a non-linearity analysis operation 803 (NONLINEAR OPERATION ANALYZER) which determines whether or not function g, used for example by auxiliary network 204, is a non-linear function. Then, according to the result of operation 803, a switching operation 805 (LINEAR?), will decide of how to carry on the method of compilation by compiler 800, according to whether function g is linear or not.

In the case where function g is non-linear (branch N), compiler 800 generates, in an operation 807 (STANDARD FLOW), a “high level” definition of a neuron layer equivalent to a “high level” definition of a circuit such as described in relation with FIG. 2A. By high level definition of a circuit, there may for example be understood a matlab representation, or a definition according to a programming format, for example the C language, or also a representation at the RTL level (“Register Transfer Level”) of the circuit. The compiler then delivers a high-level representation of circuit such as schematically shown by its main bricks illustrated in reference 807.

In the case where function g is linear (branch Y), an operation decomposer 809 (OPERATION DECOMPOSER) receives function g as well as layer function f and matrix Ω and generates to latent functions lf and g̃ enabling the implementation, in an operation 811, of the implementation of a neural network such as described in relation with FIG. 3. According to the type of the auxiliary networks, function g̃ decomposes into multiples operations. As an example, when the network is of the type described in relation with FIG. 6, function g̃ decomposes into convolutions with filters F followed by a combination with random vectors ρ₁.

Although FIG. 8 illustrates the supply of functions f and g, described in relation with FIGS. 2 and 3, operation 803 enables to determine the linearity or not of the functions σ₁ and σ₂ described in relation with FIGS. 6 and 7 and operation 809 enables, if present, to decompose the convolution kernels as described in relation with FIG. 7.

Operation 809 thus delivers a “high level” definition of a neuron layer corresponding to a “high level” definition of a “decomposable” circuit such as schematically shown, by its main bricks illustrated in reference 811.

In addition to the previously described steps of functional analysis of the compiler, the circuit computer design tool may comprise the carrying out of other design steps aiming, based on the “high-level” circuit representations, at performing the generation of other “lower-level” design files. Thus, the computer design tool enables to deliver one or a plurality of design files showing EDA (“Electronic Design Automation”) views, and/or a HDL (“Hardware Description Language”) view. In certain cases, these files, often called “IP” (Intellectual Property), may be in configurable RTL (“Register Transfer Level”) language. This circuit computer design thus enables to define for example in fine the circuit in a file format (conventionally gds2 file) which allows its manufacturing in a manufacturing site. In certain cases, the final output file of the circuit design operation is transmitted to a manufacturing site to be manufactured. It should be noted that as known per se, the files supplied by the compiler may be transmitted in a format of higher or lower level to a third party for its use by this third party in its circuit design flow.

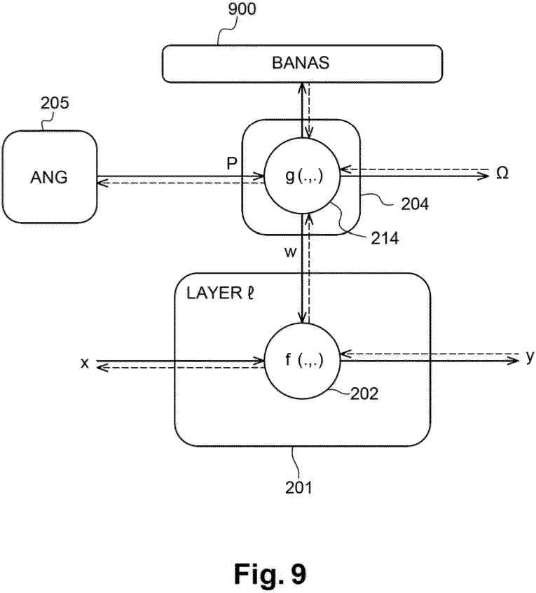

FIG. 9 is a block diagram illustrating an implementation of an automated neural architecture search tool 900 according to an embodiment of the present disclosure.

Automated search tool 900 is implemented in software fashion by a computer. Search tool 900 for example aims at selecting, among a plurality of candidate topologies, topologies for the implementation of main 201 and generative 204 or 505 networks as well as a topology for the implementation of number generator 205. The selection performed by search tool 900 responds to certain constraints such as the capacity of memories, the type of operations, the maximum number of MACs, the desired accuracy on the inference results, or any other hardware performance indicator. The automated search tool implements a search technique known as NAS (Neural Architecture Search). This search takes into account a set of optimization criteria and is called “BANAS” for “Budget-Aware Neural Architecture Search”. Further, the automated neural search tool (NAS) may be adapted to take into account the specificity of a neuron layer according to an embodiment of the invention using an on-the-fly generation of the network parameters from a sequence of numbers supplied by a random number generator. The arrows shown in dotted lines in FIG. 9 illustrate the fact that this BANAS search tool attempts to optimize the topology of the neural network by considering on the one hand the learning operations and their performance according to the topology of the network and on the other hand the performance metrics which are desired to be optimized such as the memory capacity, the computing capacity, the execution speed.

According to an embodiment, search tool 900 is coupled with the compiler 800 described in relation with FIG. 8. Search tool 900 submits a candidate topology for number generator 205 (specifying the input data: SEQUENCE LENGTH m; RANDOM SEED; EVOLUTION RULE) to compiler 800 as well as a topology of auxiliary network 204 or 505 (specifying the input data g; f; and Ω).

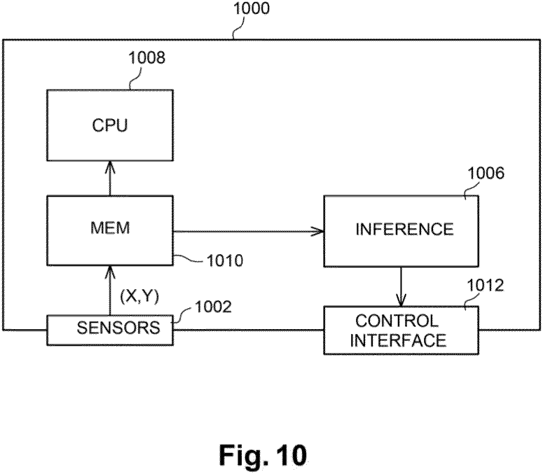

FIG. 10 illustrates a hardware system 1000 according to an example of embodiment of the present disclosure. System 1000 for example comprises one or a plurality of sensors (SENSORS) 1002, which for example comprise one or a plurality of sensors of imager type, depth sensors, thermal sensors, microphones, voice recognition tools, or any other type of sensors. For example, in the case where sensors 1002 comprise an imager, the imager is for example a visible light imager, an infrared imager, a sound imager, a depth imager, for example, of LIDAR (“Light Detection and Ranging”) type, or any other type of imagers.

Said one or a plurality of sensors 1002 supply new data samples, for example raw or preprocessed images, to an inference module (INFERENCE) 1006 via a buffer memory 1010 (MEM). Inference module 1006 for example comprises the deep neural network described in relation with FIGS. 2 to 7. In certain embodiments, certain portions of this deep neural network are implemented by a processing unit (CPU) 1008 under control of instructions stored in a memory, for example, in memory 1010.

In operation, when a new data sample is received, via a sensor 1002, it is supplied to inference module 1006. The sample is then processed, for example, to perform a classification. As an example, when the sample is formed of images, the performed inference enables to identify a scene by predicting for example the object shown in the image such as a chair, a plane, a frog, etc. In another example, the sample is formed of voice signals and the inference enables to perform, among others, voice recognition. Still in another example, the sample is formed of videos, and the inference for example enables to identify an activity or gestures. Many other applications are possible and are within the abilities of those skilled in the art.

An output of inference module 1006 corresponding to a predicted class is for example supplied to one or a plurality of control interfaces (CONTROL INTERFACE) 1012. For example, control interfaces 1012 are configured to drive one or a plurality of screens to display information indicating the prediction, or an action to be performed according to the prediction. According to other examples, the control interfaces 1012 are configured to drive other types of circuits, such as a wake-up or sleep circuit to activate or deactivate all or part of an electronic chip, a display activation circuit, a circuit of automated braking of a vehicle, etc.

Various embodiments and variants have been described. Those skilled in the art will understand that certain features of these various embodiments and variants may be combined, and other variants will occur to those skilled in the art. In particular, various configurations of number generators 205 may be used. Generator 205 may be a pseudo-random number generator having as a hardware implementation a linear feedback shift register (LFSR), a cellular automaton, or any hardware implementation capable of generating sequences of numbers. Various settings of generator 205 are also possible. The generated number may be binary numbers, integers, or also floating numbers. The initialization of the generator may be set previously or time-stamped, the seed then for example being the value of a clock of the circuit.

When generator 205 and/or 505 is a cellular automaton, a number generation rule may be learnt during the learning of the deep neural network to thus for example define the best initialization of the generator.

Finally, the practical implementation of the described embodiments and variations is within the abilities of those skilled in the art based on the functional indications given hereabove.

1. Circuit comprising:
a number generator configured to generate a sequence of vectors ρₜ, ρᵢ₊₁ of size m, the vector sequence being the same at each start-up of the number generator;
a memory configured to store a set of first parameters Ω,F, D of an auxiliary neural network;
a processing device configured to generate a set of second parameters W of a layer of a main neural network by the application a plurality of times of a first operation g, by the auxiliary neural network, performing a generation operation from each vector ρ₁ generated by the number generator, each generation delivering a vector of second parameters W₁,
the set of the vectors of second parameters forming said set of second parameters; and wherein the number of second parameters is greater than the number of first parameters.

2. Circuit according to claim 1, wherein the first operation is non-linear.

3. Circuit according to claim 1, further comprising a volatile memory configured to store the vectors of the vector sequence.

4. Circuit according to claim 3, wherein the number generator is configured to store the first vector ρ₁ into the volatile memory and to generate a second vector ρ₂, wherein the second vector is stored in the memory, causing the suppression of the first vector.

5. Circuit according to claim 1, wherein the processing device is further configured to perform an inference operation through said layer of the main neural network by applying at least one second function f based on the second parameters W₁ and on an input vector x of said layer, the operation of inference through the neuron layer delivering an output vector y, and wherein the size n_{Q} of the output vector is greater than the size m of a vector generated by the number generator.

6. Circuit according to claim 5, wherein the output vector y is generated, by the layer of the main neural network, coordinate by coordinate, by application of at least the second function f to the second parameters W₁ and to the input vector x.

7. Circuit according to claim 6, wherein the input vector is an image.

8. Circuit according to claim 1, wherein the layer of the main neural network is a dense layer or a convolutional layer.

9. Circuit according to claim 1, wherein the number generator is a cellular automaton.

10. Circuit according to claim 1, wherein the number generator is a pseudo-random number generator, the number generator for example being a linear feedback shift register.

11. Compiler implemented by computer by a circuit design tool, the compiler receiving a topological description of a circuit described as comprising:
a number generator configured to generate a sequence of vectors of size m, the vector sequence being the same at each start-up of the number generator;
a memory configured to store a set of first parameters of an auxiliary neural network;
a processing device configured to generate a set of second parameters of a layer of a main neural network by the application a plurality of times of a first operation, by the auxiliary neural network, performing a generation operation from each vector generated by the number generator, each generation delivering a vector of second parameters,
the set of the vectors of second parameters forming said set of second parameters; and wherein the number of second parameters is greater than the number of first parameters, wherein the processing device is further configured to perform an inference operation through said layer of the main neural network by applying at least one second function based on the second parameters and on an input vector of said layer, the operation of inference through the neuron layer delivering an output vector, and wherein the size n₀ of the output vector is greater than the size m of a vector generated by the number generator,
the topological description specifying the first g and second (ƒ function as well as the configuration of the number generator, the compiler being configured to determine whether the first operation g is linear or non-linear, and if the first operation is non-linear, the compiler being configured to generate a design file for the circuit.

12. Compiler according to claim 11, configured to perform, in the case where the first operation g is linear, the design of a circuit so that the circuit implements a decomposition of operations by sequentially applying a third operation lf and a fourth operation g equivalent to the combination of the first operation g and of the second operation-(f), the third operation taking as input variables the input vector x and the first parameters Ω, F, D and the fourth operation taking as inputs the sequence of vectors ρ₁ generated by the number generator and the output of the third operation lf and delivering said output vector y, Y.

13. Method of computer design of a circuit, the circuit comprising:
a number generator configured to generate a sequence of vectors of size m, the vector sequence being the same at each start-up of the number generator;
a memory configured to store a set of first parameters of an auxiliary neural network;
a processing device configured to generate a set of second parameters of a layer of a main neural network by the application a plurality of times of a first operation, by the auxiliary neural network, performing a generation operation from each vector generated by the number generator, each generation delivering a vector of second parameters,
the set of the vectors of second parameters forming said set of second and wherein the number of second parameters is greater than the number of first parameters,
the method comprising:
the implementation of a method for searching for an optimal topology of the main and/or generative neural network;
delivering a topological description of the circuit comprising the optimal topology to a compiler implemented by a circuit design tool; and
generating, by the compiler, a design file for the circuit.

14. Data processing method comprising, during an inference phase:
the generation of a vector sequence ρᵢ, ρᵢ₊₁, of size m, by a number generator, the vector sequence being the same at each start-up of the number generator;
the storage of a set of first parameters Ω, F, D of an auxiliary neural network in a memory;
the generation, by a processing device, of a set of second parameters W of a layer, of a main neural network by application a plurality of times of a first operation g, by the auxiliary neural network, performing an operation of generation from each vector ρₜ generated by the number generator, each generation delivering a vector of second parameters Wₜ, the set of vectors of second parameters forming said set of second parameters; and wherein the number of second parameters is greater than the number of first parameters.

15. Method according to claim 14, further comprising phase of learning of the auxiliary neural network, prior to the inference phase, the learning phase comprising the learning of a matrix of weights Ω, based on the vector sequence generated by the number generator, the vector sequence being identical to the vector sequence generated in the inference phase.
